(19) United States
(12) Patent Application Publication
(10) Pub. No.: US 2004/0109516 A1
(43) Pub. Date: Jun. 10, 2004

(54) Method and apparatus for compensating DC offsets in communication systems

(76) Inventor: Helena D. O'Shea, San Diego, CA (US)

Correspondence Address: Qualcomm Incorporated, Patents Department, 5775 Morehouse Drive, San Diego, CA, 92121-1714, US

(21) Appl. No.: 10/722,229

(22) Filed: Nov. 25, 2003

Related U.S. Application Data
(63) Continuation-in-part of application No. 10/600,499, filed on Jun. 19, 2003.
(60) Provisional application No. 60/390,585, filed on Jun. 20, 2002.

(51) Int. Cl. H03D 1/00

(52) U.S. Cl. 375/340

(57) ABSTRACT

A communications system has a demodulator having an output and a time-averaged DC component subtracter unit coupled to the output of said demodulator to subtract a time-averaged DC offset component from the signal at the output of the demodulator.

This application is a continuation-in-part of copending U.S. patent application Ser. No. 10/600,499, filed Jun. 19, 2003, which claims priority to U.S. provisional patent application Ser. No. 60/390,585, filed on Jun. 20, 2002.

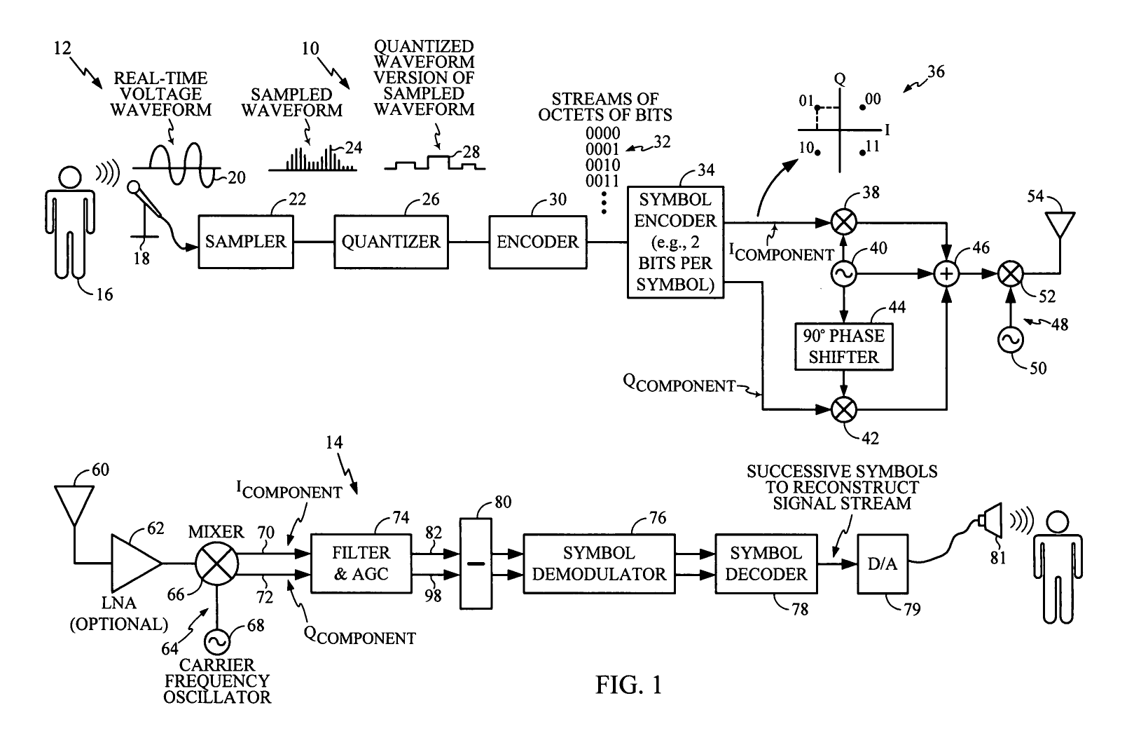

FIG. 1 is a block diagram of a wireless data communications system 10, which includes a transmitter 12 and a receiver 14. At the transmitter 12, as a user 16 speaks into a microphone 18, it converts the sound energy of the user's voice into analog electrical signals having a real-time voltage waveform 20. Although the example shown is described in terms of converted sound energy of a user's voice, the operation of the transmitter 12 is the same, or substantially the same, with respect to other types of signals as well. With appropriate modifications, the transmitter 12, as well as the receiver described below, may also be used to transmit and receive digital signals, the analog embodiment being shown only by way of example.

With reference again to the analog embodiment, a sampler 22 converts the analog electrical signals into discrete electrical signals to provide a sampled waveform 24. A quantizer 26 quantizes the discrete electrical signals into pulse amplitude modulation voltages, representing a quantized waveform version of the sampled waveform 28. An encoder 30 encodes the quantized discrete electrical signal into a string of bits, for example, represented by a stream of eight bit words, or octets 32. The octets are encoded by a symbol encoder 34 according to a symbol encoding scheme. Thus, for example, the symbol encoder 34 encodes each successive two bits of each octet to provide a stream of two bit symbols.

The symbols produced by the symbol encoder 34 represent the values of I_{component} and Q_{component} vectors such that their vector sum results in an appropriate value under the defined signal scheme. The I_{component} vector is multiplied in multiplier 38 by a first sine wave produced by oscillator 40 to produce a modulated “in-phase” (I) signal. On the other hand, the Q_{component} vector is multiplied in multiplier 42 by a second sine wave produced by the oscillator 40 that has been shifted 90° by a 90° phase shifter 44 to produce a modulated “quadrature-phase” (Q) signal. The I and Q modulated signals are added by an adder 46 together with the sine wave produced by oscillator 40 to produce a composite signal, which is received by modulator 48 to modulate a carrier sine wave. The modulator 48 includes an oscillator 50 and multiplier 52, which multiplies the composite and the oscillator signals to produce the modulated carrier signal, which is then transmitted by an antenna 54.

At the receiver 14, the transmitted signal is received by an antenna 60, which feeds the received signal into a low noise amplifier (LNA) 62, the output of which is connected to a mixer 64. The mixer 64 includes a multiplier 66 and oscillator 68 arranged to produce quadrature output signals on lines 70 and 72. The signals on lines 70 and 72 are connected to a filter and automatic gain control unit (AGC) 74. The filter and AGC unit 74 automatically adjusts the gain applied to the output signals from the AGC 74 as a function of the strength of the modulated carrier received via antenna 60, in order to maintain a relatively constant output signal level.

The quadrature output signals from the filter and AGC unit 74 are connected through a subtracter 80, below described in detail, to a symbol demodulator 76, which demodulates the automatic gain controlled version of the received signal to produce both the in-phase (I) signal and the quadrature-phase (Q) signals, which respectively represent the received values of the I_{component} vector and Q_{component} vector signals. Thereafter, a symbol decoder 78, which may be a quadrature phase shifted keyed (QPSK) decoder, uses the two bit values of the I_{component} and Q_{component} vectors to produce the decoded successive symbol bits in a stream of reconstructed octet words. The reconstructed octet words are then passed to D/A converter 79, which outputs an analog electrical signal which is converted into sound energy by speaker 81. In processing a digital signal, the output from the signal decoder may be separately processed, without need for the D/A converter 80.

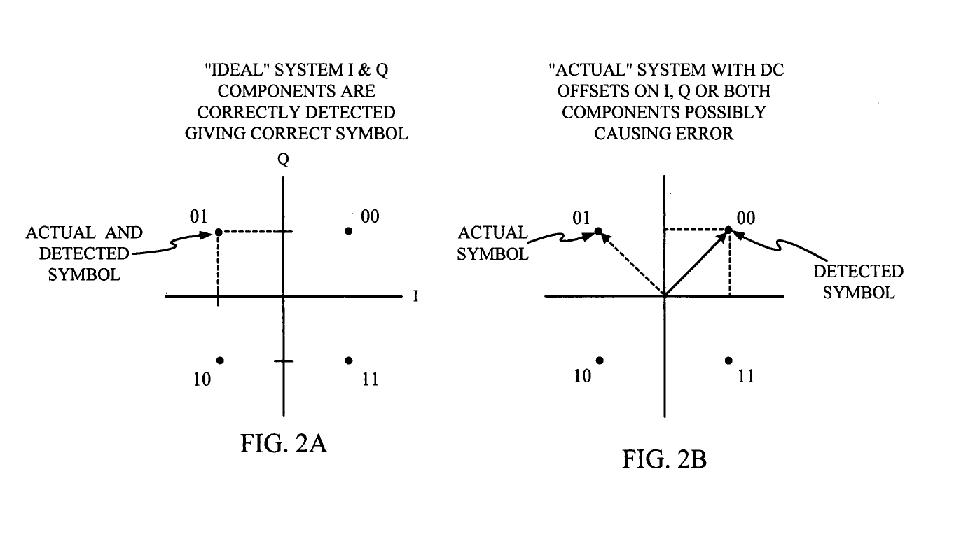

Referring additionally now to FIG. 2a, a map of the I and Q inputs to the symbol decoder 76 in an “ideal,” or theoretical, system, are shown. In the ideal system, both the I and Q components are always detected correctly by the symbol decoder 78. For instance, in the example shown, respective I and Q values “0” and “1” are properly decoded as “01”.

However, in an actual, physical system, an example of the signal map of which is shown in FIG. 2b, without the use of the subtracter 80 system irregularities give rise to direct current (DC) offset voltages on either or both the I and Q components. Factors that may cause the values of the I and Q value to contain a DC offset, for example, include the presence of noise and variations of the signal strength of the received signal, as well as component and circuit imbalances and designs in the receiver system. Moreover, due to the effects of the AGC 74, the DC offsets will tend to vary over time. Such time-varying DC offsets may be difficult to compensate.

Insofar as symbol decoder 78 relies upon both the sign and magnitude of the detected voltages of the respective I and Q components in order to correctly decode a received symbol, the presence of DC offset voltages can result in symbol decoder 78 incorrectly decoding a received symbol. In the example shown, for example, the respective values for I and Q of “0” and “1” shown in FIG. 2a have erroneously been detected as “00”, shown in FIG. 2b.

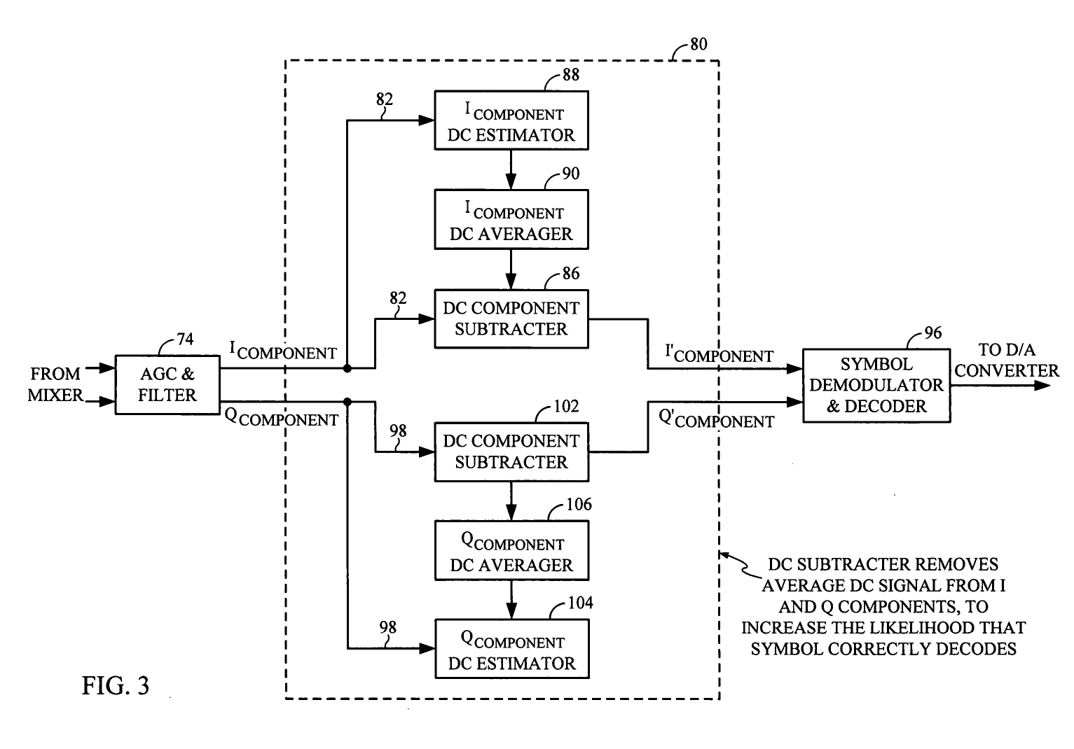

The DC offsets which may be present in the received signals, however, can be substantially reduced or eliminated, regardless of whether AGC 74 is causing such DC offsets to change over time, through the use of the subtracter 80 and methods illustrated in the block diagram of FIG. 3, to which reference is now additionally made.

The subtracter 80 is placed between the filter & AGC 74 and the symbol demodulator 76 and symbol decoder 78 in the receiver portion of the system 10 (the symbol demodulator 76 and symbol decoder 78 being represented for convenience as a single block 96). Briefly, in the subtracter 80, a time-averaged value of the DC offsets of both I and Q components are substantially removed or eliminated before symbol decoding is performed.

In the subtracter 80, the demodulated in-phase I_{component} signal on line 82 is fed into an I_{component} DC estimator 88. The DC estimator 88 determines an instantaneous DC level in the I_{component} signal, such as through low pass filtering techniques, or the like. The output of the I_{component} DC estimator 88 is fed into an I_{component} DC averager 90, which calculates a time-average of its DC input. The average may be calculated and updated periodically, for example, over successive predetermined time intervals, or may be maintained as a running average over a predetermined number of preceding average calculated values, or may be performed by another averaging technique. One way by which the average may be calculated, for example, is by summing a predetermined number of output values from the DC estimator 88 and calculating a mean value.

The output of the I_{component} DC averager 90 is fed into the DC component subtracter 86, which subtracts the time-averaged DC component from the demodulated in-phase I_{component} signal on line 82. The output of the DC component subtracter 86 I′_{component}, which represents the I_{component} value having any DC offset that may be contained therein substantially removed, then is fed into the symbol demodulator and decoder 96.

At the same time, in the quadrature signal channel, the demodulated quadrature-phase Q_{component} signal on line 98 is fed into a Q_{component} DC estimator 104. The DC estimator 104 determines an instantaneous DC level in the Q_{component} signal, using techniques described above with respect to the I_{component} DC estimator 88. The output of the Q_{component} DC estimator 104 is fed into a Q_{component} DC averager 106, which calculates a time-average of its DC input using, for example, techniques described above with respect to the Q_{component} DC averager 90.

The output of the Q_{component} DC averager 106 is fed into the DC component subtracter 102, which subtracts the time-averaged DC component from the demodulated quadrature-phase Q_{component} signal on line 98. The output of the DC component subtracter 102 Q′_{component}, which represents the Q_{component} value having any DC offset that may be contained therein substantially removed, then is fed into the symbol demodulator and decoder 96.

The systems, functions, and operations described in the block diagrams, graphs, or examples above may be implemented, individually or collectively, in hardware, software, firmware, or a combination thereof. For example, the functions may be implemented in application specific integrated circuits (ASICs), standard integrated circuits, as one or more computer programs running on a computer, computer system, one or more controllers (e.g., microcontrollers), one or more processors (e.g., microprocessors), or any combination thereof. In addition, the processes, methods, or techniques of the invention may be distributed as a program product in a variety of forms, such as may be incorporated in a digital storage medium, or the like.

1. A wireless communications system, comprising:
a transmitter for transmitting a modulated carrier comprising in-phase and quadrature-phase signals;
a receiver, comprising:
an antenna for receiving said modulated carrier;
an amplifier for amplifying said received modulated carrier;
a symbol demodulator, for demodulating said amplified modulated carrier into in-phase and quadrature-phase symbol representations having DC offset components;
a symbol decoder having in-phase and quadrature-phase inputs;
a subtracter for receiving said in-phase and quadrature-phase symbol representations and for subtracting time-averages of said DC offset components therefrom to produce in-phase and quadrature-phase inputs without DC offset components to said symbol decoder; and
a d/a converter for producing an analog signal from an output of said symbol decoder; and
a transducer for converting said analog signal to an acoustic signal.

2. The communications system of claim 1 further comprising an automatic gain control circuit between said antenna and said symbol demodulator.

3. The communications system of claim 1 further comprising a DC averager for receiving said in-phase and quadrature-phase symbol representations, producing a time-average of said DC component over a predetermined time, and providing said time-average to an input of said subtracter.

4. The communications system of claim 1 further comprising an estimator for receiving an output of said low pass filter to provide an estimate of said low pass filter output, and an averager for receiving said estimate to produce said time-average of said DC component.

5. A wireless communications receiver, comprising:
an antenna for receiving a modulated carrier;
an amplifier for amplifying said received modulated carrier;
a symbol demodulator, for demodulating said amplified modulated carrier into in-phase and quadrature-phase symbol representations having DC offset components;
a symbol decoder having in-phase and quadrature-phase inputs;
a subtracter for receiving said in-phase and quadrature-phase symbol representations and for subtracting a time-average of said DC offset components therefrom to provide in-phase and quadrature-phase inputs to said symbol decoder with substantially reduced DC offset components;
a d/a converter for producing an analog signal from an output of said symbol decoder; and
a transducer for converting said analog signal to an acoustic signal.

6. The communications receiver of claim 5 further comprising an automatic gain control circuit between said antenna and said symbol demodulator.

7. The communications receiver of claim 5 further comprising a DC averager for receiving said output, producing a time-average of said DC component over a predetermined time, and providing said time-average to an input of said subtracter.

8. The communications receiver of claim 5 further comprising a low pass filter for receiving said output, an estimator for receiving an output of said low pass filter to provide an estimate of said low pass filter output, and an averager for receiving said estimate to produce said time-average of said DC component.

9. The communications receiver of claim 5 wherein said transducer is a speaker.

10. In a wireless communications system, a receiver comprising:
a demodulator having an output with a DC component; and
a subtracter for receiving said output and subtracting a time-average of said DC component therefrom.

11. The receiver of claim 10 further comprising a DC averager for receiving said output, producing a time-average of said DC component over a predetermined time, and providing said time-average to an input of said subtracter.

12. The receiver of claim 10 further comprising a low pass filter for receiving said output, an estimator for receiving an output of said low pass filter to provide an estimate of said low pass filter output, and an averager for receiving said estimate to produce said time-average of said DC component.

13. The receiver of claim 10 wherein said output of said demodulator comprises an in-phase output and a quadrature-phase output.

14. The receiver of claim 10 wherein said subtracter unit is coupled to a symbol decoder.

15. A method comprising:
receiving a demodulator output signal;
subtracting a time-averaged DC component from the demodulator output signal to obtain a resultant signal; and
transmitting the resultant signal to a symbol decoder.

16. The method of claim 15 further comprising time averaging a DC component of the demodulator output signal to obtain the time-averaged DC component.

17. The method of claim 15 wherein said receiving a demodulator output signal comprises:
receiving an in-phase output and a quadrature-phase output of the demodulator.

18. A method for compensating DC offsets in a wireless communications system comprising:
receiving a demodulator output signal having a DC offset;
determining a time-average of said DC offset over a predetermined time;
subtracting said time-average of said DC offset from said demodulator output signal to obtain a resultant signal; and
transmitting the resultant signal to a symbol decoder.

19. The method of claim 18 wherein said receiving a demodulator output signal comprises receiving an in-phase output and a quadrature-phase output of the demodulator.

20. The method of claim 18 wherein said determining a time-average of said DC offset comprises low-pass filtering said demodulator output signal; estimating a DC component in said low-pass filtered demodulator output signal, and averaging said estimated DC component over a predetermined time.
